(19) United States
(12) Patent Application Publication
(10) Pub. No.: US 2008/0182210 A1
(43) Pub. Date: Jul. 31, 2008

(54) Image-projecting system, such as a projection objective of a microlithographic projection exposure apparatus

(75) Inventor: Karl-Heinz Schuster, Koenigsbronn (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 12/027,731

(22) Filed: Feb. 7, 2008

Related U.S. Application Data
(63) Continuation of application No. PCT/EP2006/065070, filed on Aug. 4, 2006.
(60) Provisional application No. 60/706,903, filed on Aug. 10, 2005.

(51) Int. Cl. G03F 7/00; G02B 3/00; C01F 7/02; C01B 33/26; C01B 33/24; C01B 21/20

(52) U.S. Cl. 430/322; 359/649; 423/600; 423/327.1; 423/331; 423/385

(57) ABSTRACT

The disclosure relates to an image-projecting system, such as a projection objective of a microlithographic projection exposure apparatus. In some embodiments, at least one optical element includes a cubic-crystalline material which at a given operating wavelength has a refractive index n that is greater than 1.6. The image-side numerical aperture NA of the image-projecting system is smaller than the refractive index n. The difference (n−NA) between the refractive index n and the numerical aperture NA of the image-projecting system is at most 0.2.

### CROSS-REFERENCE TO RELATED APPLICATIONS

This application is a continuation of, and claims priority under 35 U.S.C. §120 to, international application PCT/EP2006/065070, filed Aug. 4, 2006, which is hereby incorporated by reference. International application PCT/EP2006/065070 claims the benefit of U.S. Ser. No. 60/706,903, filed Aug. 10, 2005.

### FIELD

The disclosure relates to an image-projecting system, such as a projection objective of a microlithographic projection exposure apparatus. The projection objective can offer the possibility to use crystalline materials of a high refractive index while at the same time limiting the negative effects of intrinsic birefringence on the image-projection properties.

### BACKGROUND

Microlithography objectives, such as immersion microlithography objectives, with a numerical aperture (NA) value of more than 1.0 are known.

### SUMMARY

In some embodiments, the disclosure provides an image-projecting system, such as a projection objective of a microlithographic projection exposure apparatus, which offers the possibility to use crystalline materials of a high refractive index and at the same time to limit the negative influence of intrinsic birefringence.

In certain embodiments, the image-projecting system, such as a projection objective of a microlithographic projection exposure apparatus, includes at least one optical element that includes a cubic-crystalline material which at a given operating wavelength has a refractive index n that is greater than 1.6, with the image-projecting system having an image-side numerical aperture NA, where the difference (n-NA) between the refractive index n and the numerical aperture NA of the image-projecting system is at most 0.2.

It has been observed that the effect of intrinsic birefringence does not increase at a linear rate with shorter wavelengths, but that it rather begins gradually at first and then increases dramatically as the wavelengths continue to get shorter. This non-linearity is all the more pronounced the more the operating wavelength in a given case approaches the absorption edge (in the UV-range) for the respective material.

According to the disclosure, the available potential for materials with the highest possible refractive indices may not used to the limit. Rather, the index of refraction may be selected just high enough, and no higher than desirable, to meet the geometric conditions so that projection light is still transmitted through the projection objective and used for the formation of an image even under the highest occurring ray angles. At the same time, the more moderate feature imposed on the magnitude of the refractive index is used for the purpose of selecting a crystal material whose absorption edge lies deeper in the UV range, so that as a result the intrinsic birefringence in the range of the operating wavelength is smaller, or shows a lesser increase, than would be the case in a material with an absorption edge at a higher point in the range.

In the case of a numerical aperture of for example NA=1.5, although materials are available which are transparent at typical operating wavelengths of 193 nm and have high refractive indices of, e.g., 1.87 (magnesium spinel) and higher, crystal materials of the highest possible refractive indices may be consciously passed over in the selection. Instead, materials may be sought and found in which the difference by which the refractive index n exceeds the image-side numerical aperture of an image-projecting system is smaller but still just adequate for the projection light to pass through the image-projecting system and contribute to the formation of the image even under the highest occurring ray angles.

According to a further aspect, an image-projecting system, in particular a projection objective of a microlithographic projection exposure apparatus, includes at least one optical element that includes a cubic-crystalline material which at a given operating wavelength has a refractive index n, with the image-projecting system having an image-side numerical aperture NA of at least 1.50, where the difference (n-NA) between the refractive index n and the numerical aperture NA of the image-projecting system is at most 0.2.

According to a further aspect, an image-projecting system, in particular a projection objective of a microlithographic projection exposure apparatus, includes at least one optical element that includes a cubic-crystalline material which at a given operating wavelength has a refractive index n and which has a planar light-exit surface, with the image-projecting system having an image-side numerical aperture NA that is smaller than the refractive index n, where the difference (n−NA) between the refractive index n and the numerical aperture NA of the image-projecting system is at most 0.2.

In some embodiments, the difference (n-NA) between the refractive index n of the optical element and the numerical aperture NA of the image-projecting system lies in the range between 0.05 and 0.20, (e.g., in the range from 0.05 to 0.15, in the range from 0.05 to 0.10). With these ranges, according to the foregoing explanation a limitation of the intrinsic birefringence is achieved through the upper limit for the refractive index, while a limitation of the overall lens volume of the projection objective is achieved through the lower limit of the refractive index.

Further criteria that may desirably be met by the materials being used according to the disclosure include adequate stability to resist air moisture and UV light, a high degree of hardness and good optical machinability and, as much as possible, non-toxic components.

In a some embodiments, the cubic-crystalline material includes an oxide which provides an adequate transmissibility with a comparably high refractive index.

The cubic-crystalline material may include sapphire (Al₂O₃) and a potassium- or calcium oxide.

In certain embodiments, the cubic-crystalline material may include at least one material selected from 7Al₂O₃.12CaO, Al₂O₃.K₂O, Al₂O₃.3CaO, Al₂O₃.SiO₂KO, Al₂O₃.SiO₂.2K and Al₂O₃.3CaO6H₂O.

The sapphire portion (Al₂O₃) in these materials can cause a broadening of the band gap, or a shift of the absorption edge into the UV range with a simultaneous increase of the refractive index, with further, index-lowering components complementing the mixed crystal, which can lead to the aforementioned reduction of the intrinsic birefringence.

In some embodiments, the cubic-crystalline material includes calcium, sodium and silicon oxide. The cubic-crystalline material may include at least one material selected from CaNa₂SiO₄ and CaNa₄Si₃O₉.

In certain embodiments, the cubic-crystalline material includes at least one material selected from Sr(NO₃)₂, MgONa₂O.SiO₂ and Ca(NO₃)₂.

The optical element can be the last refractive lens on the image side of the image-projecting system.

In some embodiments, the optical element is composed of a first partial element with refractive power and a second partial element with essentially no refractive power. The first partial element in this arrangement is a substantially planar-convex lens, and the second partial element is a planar-parallel plate.

A design of this kind for the optical element has the advantage that can provide provides an especially effective correction of the spherical aberration, which for high aperture values typically represents the largest contribution to the image-projection errors that need to be dealt with. If the ray geometry in the area of the optical element is telecentric, the planar-parallel partial element in particular can provide an advantageous way to achieve a correction of the spherical aberration that is uniform over the image field.

In contrast to the first partial element with refractive power (i.e. specifically the planar-convex lens), the compensation paths in the second partial element which has substantially no refractive power and is composed of mutually rotated parts of the same crystallographic cut are substantially equal, so that at least in this regard it is possible to achieve an effective correction of the intrinsic birefringence by way of the clocking scheme. Accordingly, it is advantageous if in the second partial element which has substantially no refractive power, a second material of a higher refractive index than the material in the first region is used, wherein this higher refractive index can in particular also be farther apart from the numerical aperture than the aforementioned difference.

In certain embodiments, the second material is selected from magnesium spinel (MgAl₂O₄), yttrium aluminum garnet (Y₃Al₅O₁₂), MgO and scandium aluminum garnet (Sc₃Al₅O₁₂).

To allow the intrinsic birefringence to be compensated through the clocking concept, the second partial element has an element axis and at least two component parts which have the same crystallographic cut and are arranged with rotated orientations relative to each other about the element axis.

In some embodiments, the first and the second of the two component parts are each of a crystallographic (111) cut and are rotated relative to each other by 60°+k*120° (k=0, 1, 2, . . . ) about the element axis.

In certain embodiments, the first and the second of the two component parts are each of a crystallographic (100) cut and are rotated relative to each other by 45°+l*90° (l=0, 1, 2, . . . ) about the element axis.

In some embodiments, the second partial element has an element axis and at least four component parts, wherein a first and a second of the four component parts are each of a crystallographic (111) cut and are rotated relative to each other by 60°+k*120° (k=0, 1, 2, . . . ) about the element axis, and wherein further a third and a fourth of the four component parts are each of a crystallographic (100) cut and are rotated relative to each other by 45°+l*90° (l=0, 1, 2, . . . ) about the element axis.

The disclosure further relates to a microlithographic projection exposure apparatus, a method for the manufacture of microstructured components, and a microstructured component.

The disclosure further relates to the use of a material as a raw material for the manufacture of an optical element in a projection objective of a microlithographic projection exposure apparatus, wherein the material is selected from 7Al₂O₃.12CaO, Al₂O₃.K₂O, Al₂O₃.3CaO, Al₂O₃.SiO₂KO, Al₂O₃.SiO₂.2K, Al₂O₃.3CaO6H₂O, CaNa₂SiO₄, CaNa₄Si₃O₉, Sr(NO₃)₂, MgONa₂O.SiO₂ and Ca(NO₃)₂.

Further embodiments of the disclosure can be found in the description as well the claims.

The disclosure is hereinafter explained in more detail with references to the attached drawings.

### BRIEF DESCRIPTION OF THE DRAWINGS

FIG. 1 is a schematic drawing that serves to explain the design of an optical element in an image-projecting system; and

FIG. 2 is a schematic representation of the principal arrangement of a microlithographic projection exposure apparatus which can include a projection objective.

### DETAILED DESCRIPTION

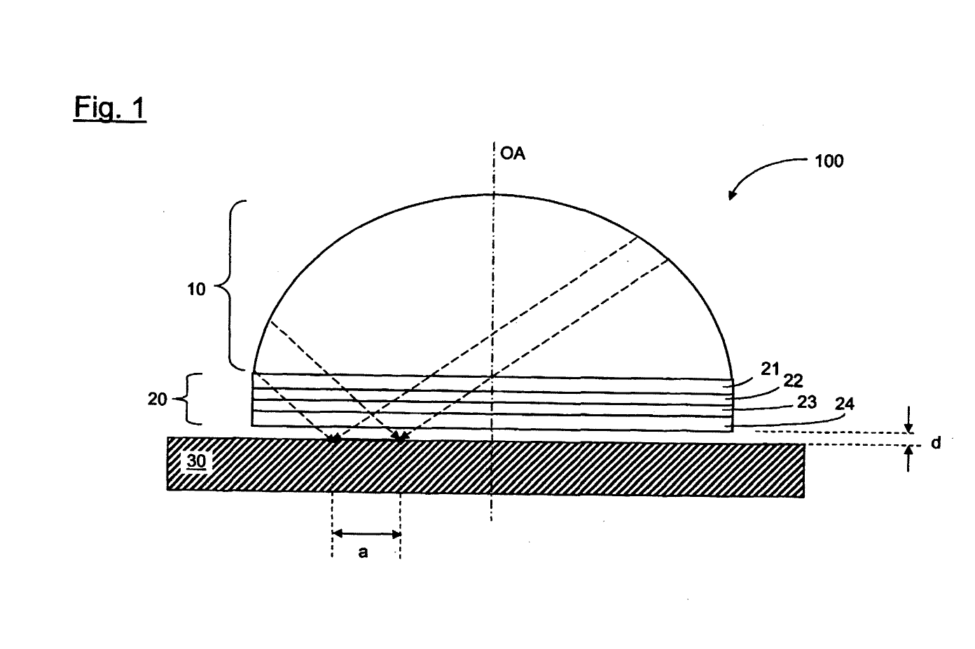

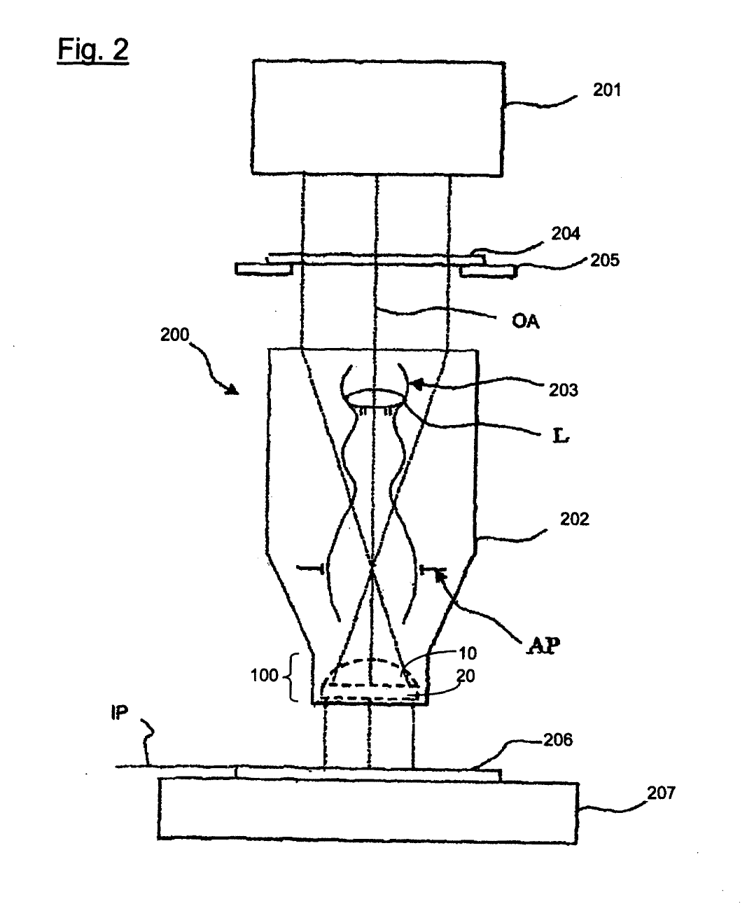

Merely as a schematic representation, FIG. 1 shows the structure of an optical element 100 in an image-projecting system according to the disclosure. The optical element 100 is typically the last lens to the image side in a microlithographic projection objective whose principal design structure will be explained hereinafter in the context of FIG. 2.

The optical element 100 illustrated in FIG. 1 is composed of a first partial element 10 in the form of a planar-convex lens and a second partial element 20 in the form of a planar-parallel plate, wherein the light entry surface of the second partial element 20 is arranged immediately adjacent to the light exit surface of the first partial element 10, such as, for example, joined to the latter by wringing. Element 30 is a wafer. Distance d represents the distance between elements 24 and 30. Distance a represents the distance between the dashed lines on the surface of element 30.

Also shown schematically in FIG. 1 is the structural composition of the second partial element 20 with a total of four component parts in the form of planar-parallel component plates 21, 22, 23 and 24. The first component plate 21 and the second component plate 22 in this arrangement each have a crystallographic (111) cut and are rotated in their orientations relative to each other by 60° (or generally by 60°+k*120°, k=0, 1, 2, . . . ) about the element axis (which in FIG. 1 coincides with the optical axis OA). The third component plate 23 and the fourth component plate 24 each have a crystallographic (100) cut and are rotated in their orientations relative to each other by 45° (or generally by 45°+l*120°, l=0, 1, 2, . . . ) about the element axis.

While shown in FIG. 2 as having four components, in some embodiments, the second partial element 20 has a total of two component parts which are of the same crystallographic cut and arranged with a rotation relative to each other about the element axis. For example, these component parts can each be of a crystallographic (100) cut and arranged with a rotation of 45°+l*90° (l=0, 1, 2, . . . ) relative to each other about the element axis, or the component parts can each be of a crystallographic (111) cut and arranged with a rotation of 60°+k*120° (l=0, 1, 2, . . . ) relative to each other about the element axis.

The first partial element 10 is made of a cubic-crystalline material of a refractive index which is selected dependent on the numerical aperture NA of the image-projecting system in such a way that the difference (n-NA) between this refractive index n and the numerical aperture NA of the image-projecting system is at most 0.2.

If one assumes as an example a numerical aperture of the projection objective of NA=1.5, the refractive index n of the cubic-crystalline material of the first partial element is accordingly at most 1.7.

A listing of materials which are particularly well suited according to the disclosure is presented in the following Table 1. The numbers listed in the second column represent the respective indices of refraction n_{d} for each crystal material at the wavelength of λ=589 nm, but it should be noted here that the refractive index at a customary wavelength of λ=193 nm is typically greater by about 0.1.

TABLE 1

| | Refractive Index n_{d} |
|---|---|
| Material | (at λ = 589 nm) |
| 7Al₂O₃•12CaO | 1.608 |
| Al₂O₃•K₂O | 1.603 |
| Al₂O₃•3CaO | 1.701 |
| Al₂O₃•SiO₂KO | 1.540 |
| Al₂O₃•SiO₂•2K | |
| Al₂O₃•3CaO6H₂O | 1.604 |
| CaNa₂SiO₄ | 1.60 |
| CaNa₄Si₃O₉ | 1.571 |
| Sr(NO₃)₂ | 1.5667 |
| MgONa₂O•SiO₂ | 1.523 |
| Ca(NO₃)₂ | 1.595 |

As illustrated in FIG. 2, a projection exposure apparatus 200 includes an illumination device 201 and a projection objective 202. The projection objective 202 contains a lens arrangement 203 with an aperture stop AP, wherein an optical axis OA is defined by the lens arrangement 203 (the latter being shown only in a schematic outline). Arranged between the illumination device 201 and the projection objective 202 is a mask 204 which is held in the ray path via a mask holder 205. Masks 204 of this kind which are used in the field of microlithography carry a structure in the micrometer-to-nanometer range which is projected via the projection objective 202, reduced for example by a factor of 4 or 5, onto an image plane IP. A light-sensitive substrate 206, specifically a wafer, is held in place in the image plane IP, positioned by a substrate holder 207. The minimum dimension of the structures that can still be resolved depends on the wavelength λ of the light being used for the illumination and also on the image-side numerical aperture of the projection objective 202, wherein the maximally achievable resolution of the projection exposure apparatus 200 increases with shorter wavelengths λ of the illumination device 201 and with larger image-side numerical aperture values of the projection objective 202. Element L corresponds to a representative a lens in lens arrangement 203.

The projection objective 202 is configured as an image-projecting system in accordance with the present disclosure. A possible approximate position of an optical element 100 according to the disclosure is indicated only schematically in broken lines in FIG. 2, wherein the optical element is arranged in accordance with some embodiments as the last optical element to the image side of the projection objective 202 and thus in the area of relatively high aperture angles. The optical element conforms to the design as explained in the context of FIG. 1 and is accordingly composed in particular of a first partial element 10 in the form of a planar-convex lens and a second partial element 20 in the form of a planar-parallel plate in accordance with the above-described embodiments.

Even though the disclosure has been described through the presentation of specific embodiments, those skilled in the pertinent art will recognize numerous possibilities for variations and alternative embodiments, for example by combining and/or exchanging features of individual embodiments. Accordingly, it will be understood that such variations and alternative embodiments are considered as being included in the present disclosure and that the scope of the disclosure is limited only by the attached patent claims and their equivalents.

What is claimed is:

1. An image-projecting system having an image-side numerical aperture, the image-projecting system comprising:
at least one optical element comprising a cubic-crystalline material having a refractive index that is greater than 1.6 at an operating wavelength of the image-projecting system,
wherein a difference between the refractive index of the cubic-crystalline material at the operating wavelength of the image-projecting system and the image-side numerical aperture of the image-projecting system is at most 0.2, and the image-projecting system is a projection objective of a microlithographic projection exposure apparatus.

2. The image-projecting system according to claim 1, wherein the difference between the refractive index of the cubic-crystalline material at the operating wavelength of the image-projecting system and the image-side numerical aperture of the image-projecting system is in the range from 0.05 to 0.20.

3. The image-projecting system according to claims 1, wherein the cubic-crystalline material comprises an oxide.

4. The image-projecting system according to claim 1, wherein the cubic-crystalline material comprises sapphire (Al₂O₃) and a potassium oxide or a calcium oxide.

5. The image-projecting system according to claim 1, wherein the cubic-crystalline material comprises at least one material selected from the group consisting of 7Al₂O₃.12CaO, Al₂O₃.K₂O, Al₂O₃.3CaO, Al₂O₃.SiO₂KO, Al₂O₃.SiO₂.2K and Al₂O₃.3CaO6H₂O.

6. The image-projecting system according to claim 1, wherein the cubic-crystalline material comprises calcium, sodium and silicon oxide.

7. The image-projecting system according to claim 1, wherein the cubic-crystalline material comprises at least one material selected from the group consisting of CaNa₂SiO₄ and CaNa₄Si₃O₉.

8. The image-projecting system according to claim 1, wherein the cubic-crystalline material comprises at least one material selected from the group consisting of Sr(NO₃)₂, MgONa₂O.SiO₂ und Ca(NO₃)₂.

9. The image-projecting system according to claim 1, wherein the optical element is a lens with refractive power located in last position to the image side of the image-projecting system.

10. The image-projecting system according to claim 1, wherein the optical element has first and second partial elements, the first partial element having refractive power, and the second partial element having substantially no refractive power.

11. The image-projecting system according to claim 10, wherein the first partial element is a substantially planar-convex lens.

12. The image-projecting system according to claim 10, wherein the second partial element is a planar-parallel plate.

13. The image-projecting system according to claim 10, wherein the cubic-crystalline material is present in the first partial element, and the second partial element comprises a second material with a greater refractive index at the operating wavelength of the image-projecting system than the refractive index at the operating wavelength of the image-projecting system of the material in the first partial element.

14. The image-projecting system according to claim 13, wherein the second material is selected from the group consisting of magnesium spinel (MgAl₂O₄), yttrium aluminum garnet (Y₃Al₅O₁₂), magnesium oxide (MgO) und scandium aluminum-garnet (Sc₃Al₅O₁₂).

15. The image-projecting system according to claim 10, wherein the second partial element has an element axis and at least two component parts that are of the same crystallographic cut and arranged with their orientations rotated relative to each other about the element axis.

16. The image-projecting system according to claim 15, wherein the first component part and the second component part are each of a crystallographic (111) cut and are arranged with their orientations rotated relative to each other by 60°+k*120° about the element axis, where k is zero or an integer having a value greater than zero.

17. The image-projecting system according to claim 15, wherein the first component part and the second component part are each of a crystallographic (100) cut and are arranged with their orientations rotated relative to each other by 45°+l*90° about the element axis, where l is zero or an integer having a value greater than zero.

18. The image-projecting system according to claim 10, wherein:
the second partial element has an element axis and first, second, third and fourth component parts;
the first component part and the second component part are each of a crystallographic (111) cut and are arranged with their orientations rotated relative to each other by 60°+k*120° about the element axis;
k is zero or an integer having a value greater than zero;
the third component part and the fourth component part are each of a crystallographic (100) cut and are arranged with their orientations rotated relative to each other by 45°+l*90° about the element axis; and
l is zero or an integer having a value greater than zero.

19. The image-projecting system according to claim 1, wherein the operating wavelength of the image-projecting system is less than 250 nm.

20. The image-projecting system according to claim 1, wherein the cubic-crystalline material comprises an alkaline earth metal.

21. The image-projecting system according claim 20, wherein the alkaline earth metal is selected from the group consisting of calcium, strontium and magnesium.

22. The image-projecting system according to claim 21, wherein the cubic-crystalline material is an oxide.

23. The image-projecting system according to claim 20, wherein the cubic-crystalline material is an oxide.

24. An apparatus, comprising:
an image-projecting system according to claim 1,
wherein the apparatus is a microlithographic projection exposure apparatus.

25. The apparatus of claim 24, wherein the image-projecting system is an immersion objective.

26. A method, comprising:
using a microlithography projection exposure apparatus according to claim 24 to provide a micro-structured component.

27. The method according to claim 26, wherein the method comprises:
projecting at least a part of a mask onto an area of a light-sensitive material on a substrate.

28. A method, comprising
forming a material into an optical element of a projection objective of a microlithographic projection exposure apparatus,
wherein the material is selected from the group consisting of 7Al₂O₃.12CaO, Al₂O₃.K₂O, Al₂O₃.3CaO, Al₂O₃.SiO₂KO, Al₂O₃.SiO₂.2K, Al₂O₃.3CaO6H₂O, CaNa₂SiO₄, CaNa₄Si₃O₉, Sr(NO₃)₂, MgONa₂O.SiO₂ and Ca(NO₃)₂.

29. An image-projecting system having an image-side numerical aperture of at least 1.5, the image projecting system comprising:
at least one optical element comprising a cubic-crystalline material having a refractive index at an operating wavelength of the image-projecting system,
wherein:
the image-side numerical aperture of the image-projecting system is less than the refractive index of the cubic-crystalline material at the operating wavelength of the image-projecting system;
a difference between the refractive index of the cubic-crystalline material at the operating wavelength of the image-projecting system and the image-side numerical aperture of the image-projecting system is at most 0.2; and
the image-projecting system is a projection objective of a microlithographic projection exposure apparatus.

30. An image-projecting system having an image-side numerical aperture, the image-projecting system comprising:
at least one optical element comprising a cubic-crystalline material comprising an alkaline earth metal, the alkaline earth metal having a refractive index at an operating wavelength of the image-projecting system,
wherein a difference between the refractive index of the alkaline earth metal at the operating wavelength and the image-side numerical aperture of the image-projecting system is at most 0.2, and the image-projecting system is a projection objective of a microlithographic projection exposure apparatus.

31. The image-projecting system according claim 30, wherein the alkaline earth metal is selected from the group consisting of calcium, strontium and magnesium.

32. The image-projecting system according to claim 31, wherein the cubic-crystalline material is an oxide.

33. The image-projecting system according to claim 30, wherein the cubic-crystalline material is an oxide.

34. The image-projecting system according to claim 30, wherein the difference between the refractive index of the alkaline earth metal at the operating wavelength of the image-projecting system and the image-side numerical aperture of the image-projecting system is in the range from 0.05 to 0.20.

35. The image-projecting system according to claim 30, wherein the difference between the refractive index of the alkaline earth metal at the operating wavelength of the image-projecting system and the image-side numerical aperture of the image-projecting system is in the range from 0.05 to 0.15.

36. The image-projecting system according to claim 30, wherein the difference between the refractive index of the alkaline earth metal at the operating wavelength of the image-projecting system and the image-side numerical aperture of the image-projecting system is in the range from 0.05 to 0.10.

37. The image-projecting system according to claim 30, where the image-side numerical aperture of the image-projecting system is at least 1.5.

38. An apparatus, comprising:
an image-projecting system according to claim 29,
wherein the apparatus is a microlithographic projection exposure apparatus.

39. The apparatus of claim 38, wherein the image-projecting system is an immersion objective.
